(19) United States
(12) Patent Application Publication
(10) Pub. No.: US 2026/0328832 A1
(43) Pub. Date: Oct. 22, 2026

(54) SEMICONDUCTOR DEVICE ANALYSIS METHOD, SYSTEM, AND NON-TRANSITORY COMPUTER-READABLE MEDIUM THEREOF

(71) Applicant: Nuvoton Technology Corporation, Hsinchu Science Park (TW)

(72) Inventor: Hen-Kai CHANG, Hsinchu City (TW)

(21) Appl. No.: 19/573,307

(22) Filed: Mar. 20, 2026

(30) Foreign Application Priority Data
Apr. 22, 2025 (TW) 114115080

(51) Int. Cl. G01R 31/26

(52) U.S. Cl. CPC G01R 31/2642

(57) ABSTRACT

A method for analyzing a semiconductor device is provided including: a training data collection step of obtaining training data including time-series data of at least one characteristic parameter of the semiconductor device measured at fixed time intervals during a first time period and a second time period longer than the first time period; a model training step of training an artificial intelligence model based on the training data to learn variation pattern of the characteristic parameter over time; an input data acquisition step of obtaining input data including time-series data of the characteristic parameter measured during the first time period in a new project; and a prediction generation step of inputting the input data into the trained artificial intelligence model, wherein the artificial intelligence model generates predicted time-series data representing the characteristic parameter of the semiconductor device for the new project during the second time period.

### CROSS REFERENCE TO RELATED APPLICATIONS

This application claims priority of Taiwan patent application No. 114115080, filed April. 22, 2025, the entirety of which is incorporated by reference herein.

### TECHNICAL FIELD

The present disclosure relates to a semiconductor device analysis method, system, and program product thereof, and, in particular, to a method, a system, and a computer-readable storage medium or a program product for performing analysis and prediction using reliability test data.

More specifically, the present disclosure relates to a technique for predicting long-term reliability characteristics of a semiconductor device, such as an analog integrated circuit (Analog IC) manufactured under a specific process, by analyzing the short-term reliability test data thereof.

### BACKGROUND

The reliability of semiconductor devices, in particular integrated circuits (ICs), is one of the key factors affecting the quality and service life of terminal electronic products. In order to ensure that semiconductor devices can operate stably for a long period of time in their actual application environments, the industry has developed various accelerated life test methods to evaluate the long-term reliability of products within a shorter period of time.

Among these, the high temperature operating life (HTOL) test is a standard test method that is widely applied to evaluate the reliability and lifetime of semiconductor devices during long-term continuous operation under specific high-temperature environments and operating voltages.

According to relevant industry standards, such as the JESD22-A108 specification established by JEDEC (Joint Electron Device Engineering Council), the execution conditions of an HTOL test typically include a specific high temperature (commonly ranging between 125 degrees Celsius and 175 degrees Celsius) and the rated operating voltage of the device (e.g., 3.3 V). During the test, a certain number of samples (e.g., from 10 to several dozens, in order to ensure statistical representativeness) are selected and subjected to long-term continuous operation testing under the aforementioned stress conditions. The total test duration is often determined by the product specifications or customer requirements, e.g., 1000 hours (hereinafter referred to as HTOL-1000). During the test period, or after completion of the test, key electrical parameters of the devices are measured to determine whether failures or significant degradation of device characteristics have occurred.

In practical semiconductor industry practice, a verified silicon intellectual property (IP) design (e.g., a specific analog IP functional block) is often repeatedly used in multiple different design projects or products developed based on the same process technology. In theory, since the same process technology and IP design are adopted (and even the layout may be completely identical), the analog IPs produced by these different projects should exhibit similar characteristics and reliability performance.

However, the actual semiconductor manufacturing process is extremely complex. Even for nominally identical process technologies, minor process variations cannot be completely avoided due to differences in time, different production lots, or subtle differences in equipment conditions. These minor variations may cause slight differences in the electrical characteristics or aging behavior of the finally produced analog IPs.

Therefore, in order to ensure that the reliability of each project or product incorporating such analog IP meets the expected specifications and requirements, in the prior art, semiconductor manufacturers or design companies often still need to extract samples and perform complete and time-consuming HTOL tests (e.g., HTOL-1000 tests lasting up to 1000 hours) for each new project, or for representative production lots, for verification. Although this approach can ensure the reliability of individual projects, its lengthy testing time is clearly unfavorable to rapid product development and market introduction.

### BRIEF SUMMARY

The primary technical problem to be solved by the present disclosure is how to significantly shorten the time required for reliability verification while ensuring sufficient confidence in the long-term reliability of an analog IP (or other semiconductor device), that is, while effectively evaluating process variation risks, so as to overcome the schedule burden caused by performing a complete long-term HTOL test in the prior art.

In other words, the present disclosure aims to provide a more efficient semiconductor device analysis method, which is expected to utilize short-term test data to accurately predict the results of long-term tests, thereby reducing or avoiding the necessity of performing a complete long-term test.

The present disclosure provides a semiconductor device analysis method. The method comprises obtaining at least one training data, wherein the training data include time-series data of at least one characteristic parameter of a semiconductor device measured at a fixed time interval during a first time period and a second time period longer than the first time period. The method comprises training an artificial intelligence model based on the training data to learn variation patterns of the characteristic parameter over time. The method comprises obtaining input data comprising time-series data of the characteristic parameter of the semiconductor device measured during the first time period in a new project when the semiconductor device is used in the new project. The method comprises generating predicted time-series data of the characteristic parameter of the semiconductor device during the second time period in the new project by inputting the input data into the trained artificial intelligence model.

In addition, the present disclosure provides a semiconductor device analysis system, comprising a memory and a processor. The memory is configured to store at least one instruction. The processor is coupled to the memory and configured to execute said instructions so that the system performs: obtaining training data including time-series data of at least one characteristic parameter of a semiconductor device measured at a fixed time interval during a second time period of a historical project in which the semiconductor device is used, the second time period including a first time period and a period after the first time period; training an artificial intelligence model stored in the memory and accessed by the processor is trained based on the training data to learn variation patterns of the characteristic parameter over time; obtaining input data comprising time-series data of the characteristic parameter obtained by measuring at least one characteristic parameter at a fixed time interval during the first time period in the new project when the semiconductor device is used in the new project; and generating predicted data of the at least one characteristic parameter of the semiconductor device during the period after the first time period of the new project by inputting the input data into the trained artificial intelligence model.

In addition, the present disclosure provides a non-transitory computer-readable medium storing instructions which, when executed by a computer, cause the computer to perform a semiconductor device analysis method comprising: obtaining training data including time-series data of at least one characteristic parameter of a semiconductor device measured at a fixed time interval during a second time period of a historical project in which the semiconductor device is used, the second time period including a first time period and a period after the first time period; training an artificial intelligence model based on the training data to learn variation patterns of the characteristic parameter over time; obtaining input data comprising time-series data of the characteristic parameter obtained by measuring at least one characteristic parameter at a fixed time interval during the first time period in a new project as input data when the semiconductor device is used in the new project; and generating predicted data of the at least one characteristic parameter of the semiconductor device during the period after the first time period of the new project by inputting the input data into the trained artificial intelligence model.

### BRIEF DESCRIPTION OF THE DRAWINGS

The present disclosure can be more fully understood by reading the subsequent detailed description and examples with references made to the accompanying drawings, wherein:

FIG. 1 is a schematic diagram illustrating a training architecture of a training stage of a semiconductor device analysis method according to one embodiment of the present disclosure;

FIG. 2 illustrates a schematic diagram showing a circuit module being applied in multiple project scenarios according to one embodiment of the present disclosure;

FIG. 3 illustrates a schematic diagram of collecting information regarding variations of characteristic parameters over time from historical project data during reliability testing according to one embodiment of the present disclosure;

FIG. 4 illustrates exemplary curves showing variations of characteristic parameters of a circuit module 20 over time, collected under different historical project scenarios according to one embodiment of the present disclosure;

FIG. 5 illustrates a schematic flow diagram of a “use stage” according to one embodiment of the present disclosure;

FIG. 6 graphically illustrates a prediction process of the use stage shown in FIG. 5, particularly how short-term measured data are connected to long-term prediction data generated by the AI model;

FIG. 7A illustrates a “data collection” and model training stage according to one embodiment of the present disclosure;

FIG. 7B illustrates a prediction and decision flow of the “use stage” according to one embodiment of the present disclosure.

### DETAILED DESCRIPTION

In order to make the objectives, technical content, features, and advantages of the present disclosure more clearly understood, the present disclosure is described in detail below with reference to the accompanying drawings and in conjunction with the embodiments. It should be noted that the following embodiments and drawings are provided for illustrative purposes only and are not intended to limit the scope of the present disclosure. Various modifications, alterations, and refinements made without departing from the spirit and principles of the present disclosure shall still fall within the scope of protection of the present disclosure. In addition, identical or similar reference numerals used in the drawings denote identical or similar elements having the same or similar functions or structures.

The present disclosure mainly provides a semiconductor device analysis method, system, and program product, which are intended to utilize an artificial intelligence model to predict long-term reliability characteristic parameters of a target semiconductor device based on short-term reliability test data thereof, and accordingly determine whether a time-consuming long-term reliability test can be omitted, so as to achieve the purposes of saving verification time and accelerating the product development process.

In one embodiment, the semiconductor device may be a circuit module, such as an analog integrated circuit (IC) or a resistor-capacitor (RC) oscillator circuit, and the characteristic parameter thereof may be an output frequency of the oscillator. The embodiments of the present disclosure will be described below with reference to the drawings.

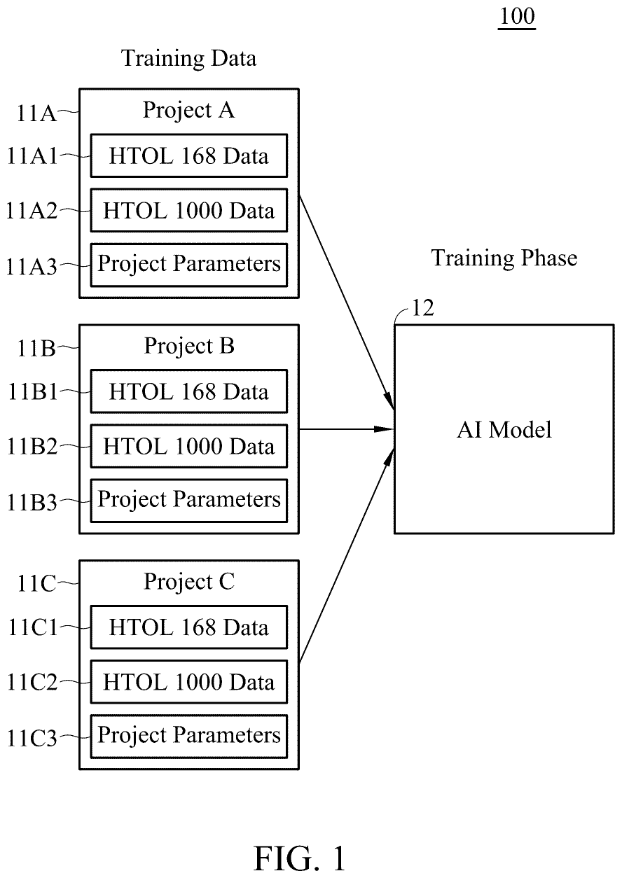

Referring to FIG. 1, which illustrates a schematic diagram of a training architecture 100 of a training phase of a semiconductor device analysis method according to one embodiment of the present disclosure. The main purpose of this phase is to establish and train an artificial intelligence model 12, such that the artificial intelligence model 12 is capable of predicting long-term aging behavior of a target semiconductor device.

In the training phase, training data is first collected. As shown in FIG. 1, the training data includes data from a plurality of historical projects or historical production lots (e.g., a first historical project data 11A, a second historical project data 11B, and a third historical project data 11C as illustrated). These historical projects all utilize the target semiconductor device (e.g., the same circuit module 20).

In one embodiment, each historical project data (taking the first historical project data 11A as an example) includes information collected during reliability testing (e.g., a High Temperature Operating Life (HTOL) test) performed on the circuit module 20 in the historical project. In one embodiment, the circuit module 20 is an RC oscillator circuit, but is not limited thereto.

In one embodiment, the first historical project data 11A includes: first time-period (e.g., HTOL-168) characteristic parameter data 11A1; second time-period (e.g., HTOL-1000) characteristic parameter data 11A2; and project parameters 11A3.

Specifically, the first time-period (e.g., HTOL-168) characteristic parameter data 11A1 is a measurement record of at least one characteristic parameter (e.g., a frequency of the RC oscillator) of the circuit module 20 of the first historical project varying with time within a relatively short test time interval (i.e., the first time period, e.g., the first 168 hours of an HTOL test). In one embodiment, the data may be time-series data obtained by measurements performed at fixed time intervals.

The second time-period (e.g., HTOL-1000) characteristic parameter data 11A2 is characteristic parameter data measured in the second time period of the first historical project, and represents a measurement record of the at least one characteristic parameter of the circuit module 20 varying with time over a complete and relatively long test time interval (i.e., the second time period, e.g., 1000 hours of an HTOL test).

In one embodiment, the second time-period characteristic parameter data 11A2 is time-series data, and a time span thereof covers the first time period and a period after the first time period until an end of the second time period. The second time-period characteristic parameter data 11A2 represents actual long-term aging behavior of the circuit module 20 and serves as a learning target of the artificial intelligence model 12, but is not limited thereto.

In one embodiment, the project parameters 11A3 of the first historical project may include other information related to the first historical project, such as specific process parameters during manufacture of the lot of devices, subtle differences in operating voltage or temperature conditions during testing, layout characteristics of the device, and other metadata, but are not limited thereto. These project parameters help the artificial intelligence model 12 learn effects of process variations or environmental factors on aging behavior.

In one embodiment, the second historical project data 11B and the third historical project data 11C also have structures and contents similar to those of the first historical project data 11A, and thus repeated descriptions are omitted herein.

In one embodiment, the second historical project data 11B includes: the first time-period characteristic parameter data 11B1, the second time-period characteristic parameter data 11B2; and project parameters 11B3. The third historical project data 11C includes: the first time-period characteristic parameter data 11C1; the second time-period characteristic parameter data 11C2; and project parameters 11C3, but is not limited thereto.

In one embodiment, the collected first historical project data 11A to third historical project data 11C collectively constitute complete training data used to train the artificial intelligence model 12. This step is an example of a “training data collection step” described in the present disclosure.

Next, in a “model training step,” the collected training data is input into the artificial intelligence model 12 for training. In one embodiment, the artificial intelligence model 12 has a model architecture with sequence data processing and generation capability, and may adopt, e.g., a generative pre-trained transformer (GPT) model, a recurrent neural network (RNN), a long short-term memory (LSTM) network, or other machine learning or deep learning models suitable for time-series prediction and generation, but is not limited thereto.

The function of the artificial intelligence model 12 lies in learning, through processing a large amount of training data, intrinsic patterns, trends, and variability of the characteristic parameters of the semiconductor device aging over time, as well as variability possibly affected by the project parameters 11A3, 11B3, and 11C3.

In one embodiment, during the training process, the artificial intelligence model 12 can learn how to generate subsequent characteristic parameter sequences starting from an initial characteristic parameter sequence (e.g., the first time-period characteristic parameter data 11A1), and to make the generated sequences as close as possible to actually measured long-term data (e.g., the second time-period characteristic parameter data 11A2). It can be understood that the artificial intelligence model 12 receives data from the first historical project data 11A to the third historical project data 11C as training inputs, but is not limited thereto. Although three sets of historical project data are illustrated in this embodiment, fewer or more sets may also be used. Although FIG. 1 only illustrates the training phase, it should be understood that the artificial intelligence model 12 trained in this phase will be used in subsequent prediction and decision phases (to be described hereinafter).

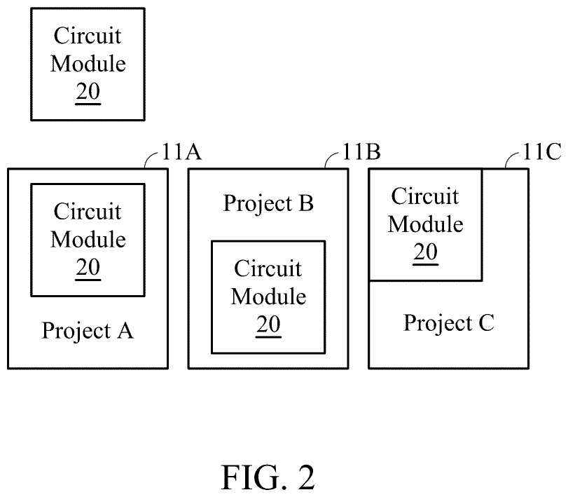

Referring to FIG. 2, which illustrates a schematic diagram showing a circuit module 20 being applied in multiple project scenarios according to one embodiment of the present disclosure. This figure illustrates a background scenario for collecting the training data shown in FIG. 1. In one specific embodiment of the present disclosure, the semiconductor device to be analyzed is the reusable circuit module 20. For example, the circuit module 20 may be a standard cell in a semiconductor process, or an analog IP block, such as the ring RC oscillator design described above. The present disclosure is particularly applicable to such circuit modules 20 that are repeatedly applied in different chip designs or different production lots under the same process technology.

As shown in FIG. 2, the same circuit module 20 design is applied in different projects, such as “Project A,” “Project B,” and “Project C” illustrated in the figure. These different project scenarios correspond to the first historical project data 11A, the second historical project data 11B, and the third historical project data 11C that provide training data sources in FIG. 1. That is, the first historical project data 11A is derived from measurement results obtained when the circuit module 20 is applied in the “Project A” scenario; the second historical project data 11B is derived from the “Project B” scenario; and the third historical project data 11C is derived from the “Project C” scenario. In FIG. 2, for ease of illustration, the circuit module 20 is shown as being located at different relative positions in Project A, Project B, and Project C to represent differences among the projects. However, the differences among the projects are not limited thereto. In one embodiment, the differences among Project A, Project B, and Project C may be represented by differences in project parameters 11A3, 11B3, and 11C3.

The technical problem to be solved by the present disclosure originates from the fact that although “Project A,” “Project B,” and “Project C” use the same circuit module 20, inevitable minor process variations occur in their respective semiconductor manufacturing processes. In addition, the chip environments into which the circuit module 20 is ultimately integrated, or the operating/testing conditions they endure, may also differ. These factors result in differences in actual characteristic parameters (e.g., RC oscillation frequency) and aging behavior over time, even for the same circuit module 20 design used in different projects. Such actually measured aging data, which includes individual differences, constitutes the first time-period characteristic parameter data 11A1, 11B1, and 11C1 (representing short-term aging results, e.g., HTOL-168), the second time-period characteristic parameter data 11A2, 11B2, and 11C2 (representing long-term aging results, e.g., HTOL-1000), and the project parameters 11A3, 11B3, and 11C3 (e.g., specific process lots, test temperatures, etc.) that may affect these results, as shown in FIG. 1.

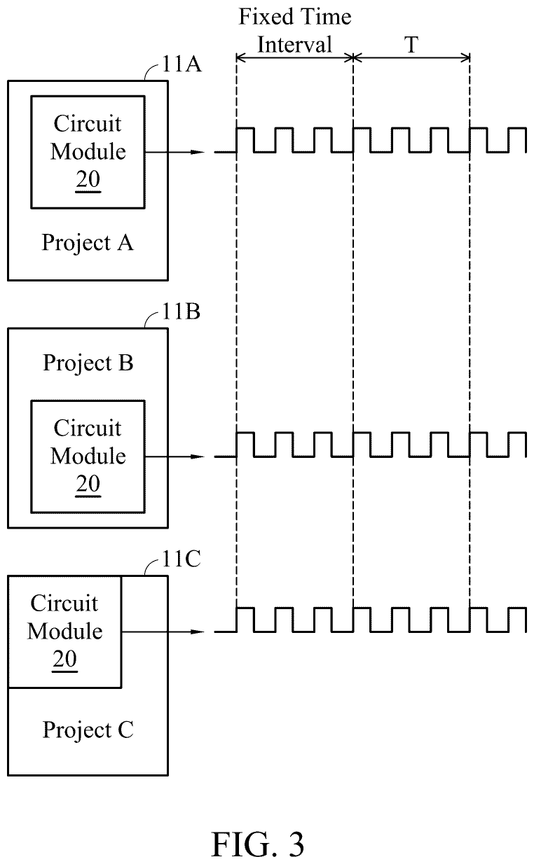

Referring to FIG. 3, which illustrates a schematic diagram of collecting information regarding characteristic parameters over time from historical project data during reliability testing according to one embodiment of the present disclosure. This figure more specifically illustrates how the time-series data in the training data (e.g., the first historical project data 11A, the second historical project data 11B, and the third historical project data 11C) shown in FIG. 1 is generated.

In one embodiment, in order to obtain detailed aging data for training the artificial intelligence model 12, reliability tests are performed for a certain period of time on different historical projects (e.g., “Project A,” “Project B,” and “Project C” schematically illustrated in FIG. 3), each of which utilizes the same circuit module 20.

In one embodiment, the reliability test may be a HTOL test, such as HTOL-1000, with a total test duration of 1000 hours, which also serves as an example of the “second time period” referred to in the present disclosure. In one embodiment, the test conditions (e.g., temperature, voltage) are set according to standard specifications (e.g., JEDEC JESD22-A108) or specific application requirements, but are not limited thereto.

During the entire test duration of the long-term reliability test, a key step is repeatedly measuring and recording at least one key characteristic parameter of the circuit module 20 at a fixed time interval T. The fixed time interval T is selected to be sufficiently frequent to capture dynamic changes in the characteristic parameter caused by aging over time, for example, it can be set to every minute, every few minutes, every hour, or another suitable interval determined based on an actual aging rate. When a ring oscillator is used as an embodiment of the circuit module 20, the measured characteristic parameter may be an output signal frequency thereof. The waveform shown on the right side of FIG. 3 schematically illustrates an output signal varying with time, and the indicated fixed time interval T represents the interval at which frequency measurements are performed.

By performing continuous or periodic measurements at the fixed time interval T throughout the entire long-term test duration (the second time period), time-series data that thoroughly describes aging behavior of the circuit module 20 under a specific project scenario can be obtained. These time-series data constitute important components of the training data shown in FIG. 1 according to the time ranges covered thereby. Specifically, data sequences corresponding to an initial shorter time range of the test (e.g., from 0 hours to 168 hours, i.e., the “first time period” described above) constitute the first time-period characteristic parameter data 11A1, 11B1, and 11C1; and complete data sequences covering the entire test duration (e.g., from 0 hours to 1000 hours, i.e., the “second time period” described above) constitute the second time-period characteristic parameter data 11A2, 11B2, and 11C2.

Such time-series data obtained based on measurements at the fixed time interval T is crucial for training artificial intelligence models 12 capable of understanding and generating sequential data (e.g., GPT, LSTM). The effectiveness thereof lies in providing rich dynamic variation information, enabling the artificial intelligence model 12 to learn complex patterns in which characteristic parameters such as frequency drift or degrade over time, rather than merely learning static values at a few discrete time points. The training data obtained in this manner (e.g., the first historical project data 11A through the third historical project data 11C shown in FIG. 1), by including temporal information, enables the trained artificial intelligence model 12 to have the capability to “continuously generate” subsequent long-term sequence data (e.g., predicted HTOL-1000 data) starting from a short-term initial sequence data segment (e.g., HTOL-168 data of the circuit module 20). This data collection and model training approach provides a solid foundation for subsequent implementation of rapid reliability prediction and decision-making in the present disclosure.

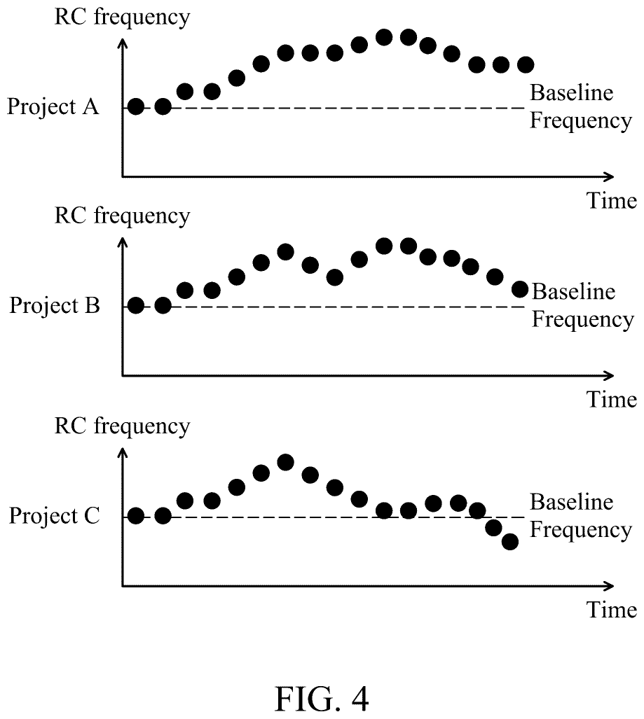

Referring to FIG. 4, which illustrates exemplary curves showing variations of characteristic parameters of a circuit module 20 (taking the frequency of an RC oscillator as an example) over time, collected under different historical project scenarios (e.g., Project A, Project B, and Project C shown in the figure, respectively corresponding to the historical project data 11A, 11B, and 11C of FIGS. 1 and 2) according to one embodiment of the present disclosure. In each sub-figure, the horizontal axis represents the duration of a reliability test (e.g., HTOL), and the vertical axis represents the measured frequency. The data points shown in the figure (e.g., solid dots) schematically represent repeated measurement results obtained at a fixed time interval T during the test period (e.g., within 1000 hours). A baseline frequency (e.g., a design target frequency or an initial measured frequency of the circuit module 20) may also be indicated in the figure for comparison of frequency drift caused by aging.

As can be observed from the example of FIG. 4, the circuit modules 20 under different historical projects (Project A, Project B, and Project C) exhibit different aging curve patterns and different degrees of frequency drift over time. This visually reflects the aforementioned individual differences caused by process variations or other factors. Such diversified time-series data that can reflect real physical behaviors constitute valuable training data for training the artificial intelligence model 12 (i.e., the first historical project data 11A to the third historical project data 11C in FIG. 1, which include the first time-period characteristic parameter data 11A1 to 11C1 and the second time-period characteristic parameter data 11A2 to 11C2, etc.).

In one embodiment, before importing such collected numerical time-series data (e.g., frequency sequences) illustrated in FIG. 4 into the artificial intelligence model 12 for training, a data preprocessing step may be included. The purpose of the data preprocessing step is to convert raw data into a specific format that is more suitable for learning by the artificial intelligence model 12. For example, the time-series values representing frequency may be converted into fixed-length vector representations, or normalization may be performed to eliminate dimensional effects or adjust numerical ranges, or techniques such as Fourier transform may be applied to extract frequency-domain features. Such preprocessing helps improve the stability and convergence speed of model training. This data preprocessing may be regarded as a preparatory operation that is broadly part of a “training data collection step” or a “model training step”, but is not limited thereto.

In a “model training step”, the artificial intelligence model 12 performs learning by using the preprocessed training data. In one embodiment, the model learns to predict or generate a corresponding long-term sequence (with a target close to the actual second time-period characteristic parameter data 11A2) from an input short-term sequence (e.g., the first time-period characteristic parameter data 11A1). This process is typically performed by iteratively adjusting internal parameters of the model to minimize a prediction error between a model output and an actual target. In one embodiment, the prediction error may be defined by a loss function, but is not limited thereto.

With respect to when to stop the model training, one or more termination conditions may be set. In addition to monitoring convergence of the loss function, in one embodiment, a practical termination condition related to product reliability specifications and expected prediction accuracy may be defined. For example, assuming that product specifications of the circuit module 20 require that, after aging in the second time period (e.g., HTOL-1000), a frequency offset relative to the baseline frequency must be controlled within ±4%. Based on historical data (e.g., the second time-period characteristic parameter data 11A2), it may be known that, in actual tests, a final frequency offset of some samples may be +2%. In such a case, a training termination condition of the artificial intelligence model 12 may be defined as follows: when prediction errors of the model, with respect to predicted long-term frequency offsets of all (or most) samples in the training data relative to actual observed values, have been reduced to within a preset tolerance range (e.g., 2%), the training will stop. Selection of such a tolerance range should take into account a balance between product specifications and prediction risk. For example, the prediction error may be required to be less than 1%. In this manner, prediction results of the model (e.g., predicted offsets falling within +1% to +3%) can both ensure a high probability of satisfying the product specification (±4%) and avoid excessive deviation from actual conditions (+2%). Setting such termination conditions based on prediction accuracy and specifications ensures that the finally trained artificial intelligence model 12 has sufficient predictive capability, and that its prediction results have practical reference value for a subsequent “decision step” for determining whether to omit a long-term test, thereby avoiding incorrect decisions caused by inaccurate predictions (overly optimistic or overly pessimistic).

The aforementioned paragraphs and corresponding figures describe in detail how to collect training data containing time-series information, and how to use such data to train the artificial intelligence model 12 to enable simulation and prediction of aging behaviors of a semiconductor device, including appropriate setting of training termination conditions.

In one embodiment, after the artificial intelligence model 12 is trained in the manner described above, the trained artificial intelligence model 52 may be deployed in a practical application to perform rapid reliability evaluation for a new target project. This constitutes a “use” stage of the method of the present disclosure, which is described in detail below.

Specifically, when a new project also adopts the same semiconductor device, only a short-term reliability test (the first time period, e.g., HTOL-168) needs to be performed on the semiconductor device to obtain first time-period characteristic parameter data as “input data”. Subsequently the input data are imported into the trained artificial intelligence model 52. Leveraging its learned aging patterns and generation capability, the artificial intelligence model 52 can generate, based on such short-term input data, a “prediction result” for the long-term duration (the second time period, e.g., HTOL-1000), namely second time-period characteristic parameter data of the target device. Since the model outputs continuous data, values corresponding to time points from an end of the first time period (HTOL-168) to an end of the second time period (HTOL-1000) may be extracted from the sequence of continuous data as the prediction result, but are not limited thereto.

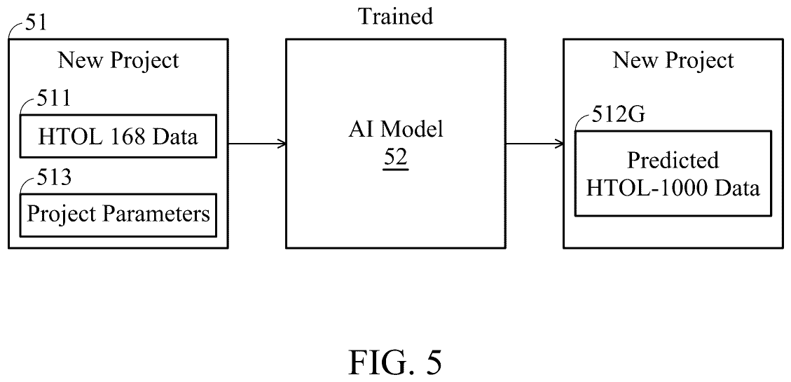

Referring to FIG. 5, a schematic flow diagram of a “use stage” according to one embodiment of the present disclosure is illustrated, showing how a trained AI model is used to perform prediction for a new project 51. The new project 51 also adopts the same circuit module 20 as those in the historical project data 11A to 11C. The “AI model” block shown in the center of FIG. 5 represents the aforementioned artificial intelligence model 52 that has been trained based on historical data.

In the use stage, operations corresponding to an “input data acquisition step” are performed for the new project 51. As shown on the left side of FIG. 5, only a short-term reliability test (e.g., HTOL-168) needs to be performed on the circuit module 20 of the new project 51 to obtain characteristic parameter time-series data within the first time period, which are denoted in the figure as first time-period (HTOL-168) characteristic parameter data. The first time-period characteristic parameter data 511 serve as actual input provided to the artificial intelligence model 52. In one embodiment, if there are specific parameters related to the new project 51, such parameters may also be provided to the model as project parameters 513.

Thereafter, operations corresponding to a “prediction generation step” are performed. The first time-period characteristic parameter data 511 (and possible project parameters 513) from the new project 51 are input into the trained artificial intelligence model 52, as indicated by arrows shown in FIG. 5.

In one embodiment, the function of the artificial intelligence model 52 is to utilize learned aging pattern knowledge to process the input sequence and to forwardly generate (predict) a characteristic parameter evolution sequence of the circuit module 20 over a subsequent longer duration (up to the end of the second time period, e.g., HTOL-1000). The model-generated output is a “prediction result”, such as the predicted second time-period (HTOL-1000) characteristic parameter data 512G shown on the right side of FIG. 5, which is one example of “predicted time-series data” of the present disclosure.

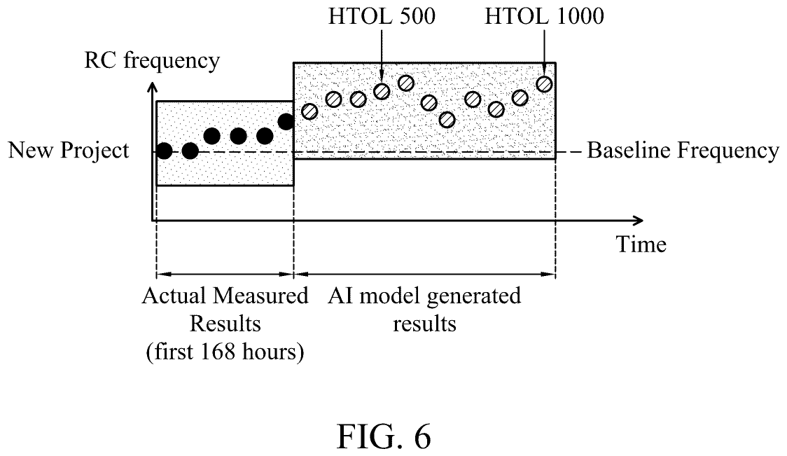

FIG. 6 more intuitively illustrates, in a graphical manner, a prediction process of the trained model shown in FIG. 5 during the use stage, particularly how short-term measured data are connected to long-term prediction data generated by the AI model. The figure illustrates a curve showing variation of a characteristic parameter (also taking RC frequency as an example) of a “new project” (corresponding to the new project 51 of FIG. 5) over time, and a baseline frequency is also indicated for comparison.

As shown in a shaded region on the left side of FIG. 6, solid data points represent characteristic parameter data sequences obtained through actual measurements during a short-term reliability test (e.g., HTOL-168, corresponding to the “first time period” defined in the present disclosure) performed for the new project. This sequence corresponds to the first time-period characteristic parameter data 511 shown in FIG. 5, and is labeled as “actual measured results (first 168 hours)”. The first time-period characteristic parameter data 511 serve as a basic input subsequently provided to the artificial intelligence model 52 for prediction.

As shown in a shaded region on the right side of FIG. 6, hollow data points represent subsequent characteristic parameter data sequences that are continuously generated (predicted) by the artificial intelligence model 52 based on the input first time-period characteristic parameter data 511 (i.e., the actual measured results on the left side). The generated sequence (labeled as “AI model generated results”) corresponds to the predicted second time-period characteristic parameter data 512G shown in FIG. 5, and represents an estimation of aging behavior of the new project over a subsequent longer duration (corresponding to the “second time period” defined in the present disclosure), for example extending from 168 hours to 500 hours (HTOL-500), 1000 hours (HTOL-1000), or longer.

FIG. 6 clearly illustrates core functions and data linkage relationships of the method of the present disclosure in the use stage: by using actually executed, shorter-duration first time-period characteristic parameter data 511 as an input “prompt”, the artificial intelligence model 12 that has previously learned aging patterns is driven to generate predicted second time-period characteristic parameter data 512G representing long-term aging behavior. The figure also schematically indicates that predicted values corresponding to specific target time points (e.g., 500 hours (HTOL-500) or 1000 hours (HTOL-1000)) may be extracted from generating the predicted second time-period characteristic parameter data 512G.

In one embodiment, a subsequent “decision step” is performed based on predicted values of the predicted second time-period characteristic parameter data 512G. By comparing such predicted values with product specifications, it can be determined whether an actual long-term test may be omitted.

In one embodiment, after obtaining the predicted second time-period characteristic parameter data 512G, operations corresponding to a “decision step” may be performed. Predicted characteristic parameter values represented by the predicted second time-period characteristic parameter data 512G (e.g., a predicted HTOL-1000 frequency offset) are compared with predetermined product reliability specifications or acceptance criteria. If comparison results indicate that the values of the predicted second time-period characteristic parameter data 512G satisfy the criteria, a decision may be made that the circuit module 20 in the new project 51 has sufficient long-term reliability, and thus an originally required, time-consuming actual long-term HTOL test (e.g., HTOL-1000) may be omitted.

Although RC oscillators (abbreviated as RC in the figures) and their frequencies are used as examples in the drawings and descriptions, the method disclosed in the present disclosure for training an AI model using historical time-series data and predicting long-term aging behavior based on short-term measured data can be applicable to other analog ICs or semiconductor devices by selecting appropriate key characteristic parameters and collecting corresponding time-series data.

In addition, to achieve better prediction performance, as disclosed in the present disclosure, data types input into the artificial intelligence model should be consistent with data types expected to be generated as outputs. For example, if variation of frequency over time is to be predicted, the input first time-period characteristic parameter data should primarily include frequency time-series data, so that the model can focus on learning and generating aging dynamics of that specific parameter.

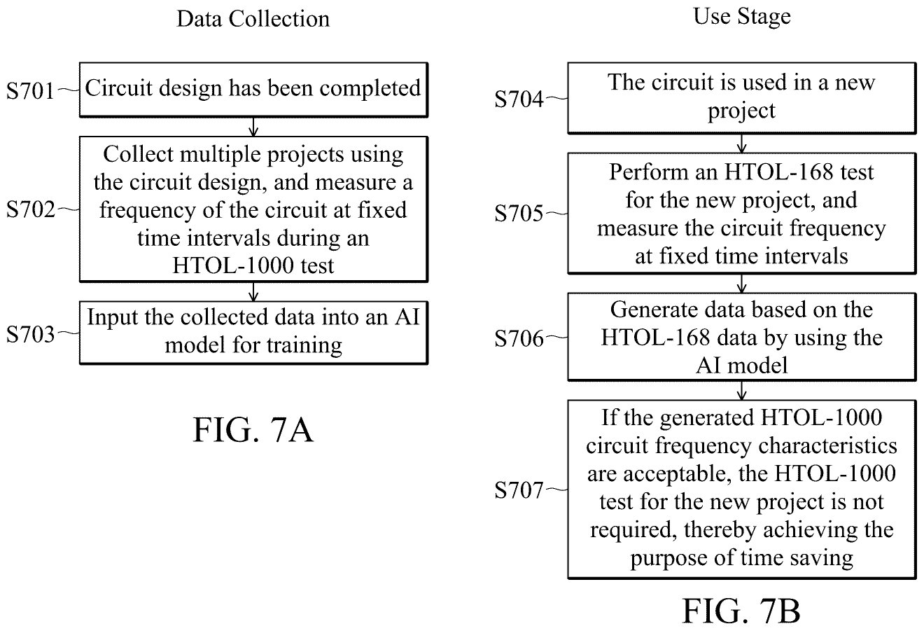

Referring to the flowcharts illustrated in FIGS. 7A and 7B. The flowcharts of FIGS. 7A and 7B fully connect core steps of the semiconductor device analysis method of the present disclosure, integrating concepts described in the foregoing embodiments and figures. FIG. 7A illustrates a “data collection” and model training stage of the method, and FIG. 7B illustrates a prediction and decision flow of the “use stage”.

In the data collection and training stage of FIG. 7A, the flow may begin at step S701, which indicates that a semiconductor device design to be analyzed (e.g., corresponding to the circuit module 20 of FIGS. 2 and 3, taking an RC oscillator as an example, abbreviated as RC in the figures) exists or has been completed.

Then, step S702 is performed, which is one example of a “training data collection step” of the present disclosure. In this step, training data are collected from at least one (preferably a plurality, such as Projects A, B, and C shown in FIG. 1) historical instance (e.g., historical production lots or historical projects) adopting the circuit module 20 design. Key contents of the training data include time-series data of at least one characteristic parameter (e.g., frequency) of the circuit module 20. The time-series data are measured at a fixed time interval T during a first time period (e.g., HTOL-168) and a second time period longer than the first time period (e.g., HTOL-1000). The collected data correspond to the historical project data 11A, 11B, and 11C shown in FIG. 1, including first time-period characteristic parameter data 11A1, 11B1, and 11C1, second time-period characteristic parameter data 11A2, 11B2, and 11C2, and project parameters 11A3, 11B3, and 11C3.

Subsequently, in step S703 (which is one example of a “model training step” of the present disclosure), the training data collected in step S702 (e.g., historical project data 11A, 11B, and 11C) are used to train the artificial intelligence model 12 (such as the training architecture 100 shown in FIG. 1). The purpose of training is to enable the artificial intelligence model 12 to learn variation patterns of the characteristic parameter (e.g., frequency) over time (covering the first and second time periods). The training process may include the aforementioned data preprocessing and termination conditions based on prediction accuracy and specifications.

Subsequently, the process enters the use stage (FIG. 7B), corresponding to applying the trained artificial intelligence model 52 to analyze a new project (e.g., the new project 51 of FIG. 5). Step S704 indicates the beginning of this scenario. In step S705 (which is one example of an “input data acquisition step” of the present disclosure), for the circuit module 20 of the new project, a reliability test corresponding to the first time period (e.g., HTOL-168) is performed, and characteristic parameters (e.g., frequency) are measured at a fixed time interval T to obtain time-series data of the first time period. The obtained data serve as input data (corresponding to the first time-period characteristic parameter data 511 of FIG. 5).

In step S706 (which is one example of a “prediction generation step” of the present disclosure), the input data from step S705 (the first time-period characteristic parameter data 511) are input into the artificial intelligence model 52 that has been trained in step S703. Based on the input short-term time-series data, the artificial intelligence model 52 performs data generation to produce predicted characteristic parameter time-series data covering the subsequent second time period (e.g., HTOL-1000). This output is “predicted time-series data” (corresponding to the predicted second time-period characteristic parameter data 512G of FIG. 5).

Finally, in step S707 (which is one example of a “decision step” of the present disclosure), prediction results generated in step S706 (the predicted second time-period characteristic parameter data 512G) are compared with predefined reliability acceptance criteria. If prediction results indicate that the criteria are satisfied (“acceptable”), a decision may be made to omit performing an actual, time-consuming second time-period test (e.g., HTOL-1000) for the new project, thereby achieving time and cost savings.

Accordingly, effects of saving test time and cost of the present disclosure are achieved. If prediction results do not satisfy the criteria, a potential risk is indicated, and a long-term test may still need to be performed for final confirmation. The complete process described above, including short-term testing, model prediction, and decision-making based on prediction results, demonstrates practical application value of the method of the present disclosure.

To sum up, through detailed descriptions of the embodiments and figures, the present disclosure fully discloses a method, system, and process for analyzing reliability of semiconductor devices using artificial intelligence models. By learning aging patterns from historical data, the method can effectively predict long-term reliability characteristics of a target device based on short-term test data, and optimize test workflows accordingly, providing significant practicality and industrial value. The contents disclosed herein are sufficient to support the appended claims of the present disclosure. The foregoing descriptions are merely preferred embodiments of the present disclosure and are not intended to limit the scope thereof. Therefore, any simple equivalent changes or modifications made in accordance with the claims and descriptions of the present disclosure shall fall within the scope of protection of the present disclosure.

What is claimed is:

1. A semiconductor device analysis method, comprising:
obtaining training data including time-series data of at least one characteristic parameter of a semiconductor device measured at a fixed time interval during a first time period and a second time period longer than the first time period;
training an artificial intelligence model based on the training data to learn variation patterns of the characteristic parameter over time;
obtaining input data comprising the time-series data of the characteristic parameter of the semiconductor device measured during the first time period in a new project when the semiconductor device is used in the new project; and
generating predicted time-series data of the characteristic parameter of the semiconductor device during the second time period in the new project by inputting the input data into the trained artificial intelligence model.

2. The semiconductor device analysis method of claim 1, wherein the artificial intelligence model comprises a generative model.

3. The semiconductor device analysis method of claim 1, wherein the first time period corresponds to a high-temperature operating life (HTOL) 168-hour test period; and
the second time period corresponds to a high-temperature operating life (HTOL) 1000-hour test period.

4. The semiconductor device analysis method of claim 3, further comprising:
comparing the predicted time-series data with a predetermined reliability criterion; and
determining to omit performing a high-temperature operating life test corresponding to the second time period on the semiconductor device when the predicted time-series data satisfy the predetermined reliability criterion.

5. The semiconductor device analysis method of claim 1, wherein the training data is obtained from time-series data of the characteristic parameter collected during a high-temperature operating life test previously performed on the semiconductor device.

6. The semiconductor device analysis method of claim 1, wherein the artificial intelligence model generates sequence data representing continuous variation of the at least one characteristic parameter over time based on the input data.

7. The semiconductor device analysis method of claim 1, wherein the semiconductor device is an analog integrated circuit (Analog IC).

8. The semiconductor device analysis method of claim 1, wherein the second time period includes a period overlapping with the first time period.

9. A semiconductor device analysis system, comprising:
a memory, configured to store at least one instruction; and
a processor, coupled to the memory and configured to execute the at least one instruction, such that the system performs:
obtaining training data including time-series data of at least one characteristic parameter of a semiconductor device measured at a fixed time interval during a second time period of a historical project in which the semiconductor device is used, the second time period including a first time period and a period after the first time period;
training an artificial intelligence model stored in the memory and accessed by the processor is trained based on the training data to learn variation patterns of the characteristic parameter over time;
obtaining input data comprising time-series data of the characteristic parameter obtained by measuring at least one characteristic parameter at a fixed time interval during the first time period in the new project when the semiconductor device is used in the new project; and
generating predicted data of the at least one characteristic parameter of the semiconductor device during the period after the first time period of the new project by inputting the input data into the trained artificial intelligence model.

10. A non-transitory computer-readable medium storing instructions which, when executed by a computer, cause the computer to perform a semiconductor device analysis method comprising:
obtaining training data including time-series data of at least one characteristic parameter of a semiconductor device measured at a fixed time interval during a second time period of a historical project in which the semiconductor device is used, the second time period including a first time period and a period after the first time period;
training an artificial intelligence model based on the training data to learn variation patterns of the characteristic parameter over time;
obtaining input data comprising time-series data of the characteristic parameter obtained by measuring at least one characteristic parameter at a fixed time interval during the first time period in the new project as input data when the semiconductor device is used in the new project; and
generating predicted data of the at least one characteristic parameter of the semiconductor device during the period after the first time period of the new project by inputting the input data into the trained artificial intelligence model.
